(19) United States
(12) Patent Application Publication
(10) Pub. No.: US 2015/0102373 A1
(43) Pub. Date: Apr. 16, 2015

(54) LIGHT EMITTING DIODE PACKAGE AND METHOD OF MANUFACTURING THE SAME

(71) Applicant: SAMSUNG ELECTRONICS CO., LTD., Suwon-si (KR)

(72) Inventors: Sang Hyun Lee, Suwon-si (KR); Dong Hyuck Kam, Hwaseong-si (KR); Yong Tae Kim, Suwon-si (KR); Gam Han Yong, Suwon-si (KR); Seung Jae Lee, Suwon-si (KR); Seong Deok Hwang, Seoul (KR)

(21) Appl. No.: 14/314,650

(22) Filed: Jun. 25, 2014

(30) Foreign Application Priority Data
Oct. 10, 2013 (KR) 10-2013-0120760

(51) Int. Cl. H01L 33/50; H01L 33/58; H01L 33/00

(52) U.S. Cl. CPC H01L 33/50; H01L 33/005; H01L 33/58
USPC 257/98; 438/27

(57) ABSTRACT

There is provided a light emitting diode (LED) package. The LED package includes a package body. The LED package also includes an LED chip mounted on the package body. The LED package further includes a side inclined portion disposed to enclose side surfaces of the LED chip, including a light transmission material and having an upwardly inclined surface. The LED package also includes a wavelength conversion layer disposed on a top surface of the LED chip and the inclined surface of the side inclined portion.

### CROSS-REFERENCE TO RELATED APPLICATION

This application claims priority to and benefit of Korean Patent Application No. 10-2013-0120760 filed on Oct. 10, 2013, with the Korean Intellectual Property Office, the entire content of which is incorporated herein by reference.

### TECHNICAL FIELD

The present disclosure relates to a light emitting diode (LED) package and a method of manufacturing the same.

### BACKGROUND

An LED is a device including a material that emits light using electric energy, in which energy generated through electron-hole recombination in semiconductor junction parts is converted into light to be emitted therefrom. LEDs are commonly used as light sources in illumination devices, display devices, and the like, and development of LEDs has thus been accelerated.

In particular, recent increase in development and employment of gallium nitride-based LEDs, and the commercialization of mobile keypads, turn signal lamps, camera flashes, and the like, using such gallium nitride-based LEDs, have led to the acceleration of the development of general illumination devices using LEDs. The purposes of LEDs are gradually moving from small portable products toward large-sized products having high output and high efficiency, such as a backlight unit of a large TV, a headlamp of a vehicle, a general illumination device, and the like. Accordingly, a method of improving light extraction efficiency in LEDs used for those purposes is required.

### SUMMARY

An aspect of the present disclosure provides a light emitting diode (LED) package in which color temperature difference is reduced and color quality is improved.

According to an aspect of the present disclosure, a light emitting diode (LED) package includes a package body, an LED chip mounted on the package body, and a side inclined portion disposed to enclose side surfaces of the LED chip. The side inclined portion includes a light transmission material and has an upwardly inclined surface. The light emitting diode (LED) package further includes a wavelength conversion layer disposed on a top surface of the LED chip and the inclined surface of the side inclined portion.

The inclined surface may be extended from an edge of the top surface of the LED chip to a mounting surface of the package body.

The inclined surface may be curved.

The inclined surface may be concavely curved with respect to a straight line connecting an edge of the top surface of the LED chip to a mounting surface of the package body.

The inclined surface may be convexly curved with respect to a straight line connecting an edge of the top surface of the LED chip to a mounting surface of the package body.

The side inclined portion may be extended to have a flat surface on the same level as the top surface of the LED chip.

The light transmission material may be a transparent resin.

The wavelength conversion layer may have a substantially uniform thickness.

According to another aspect of the present disclosure, an LED package includes a package body including a first electrode structure and a second electrode structure. The LED package also includes an LED chip having a first electrode and a second electrode disposed on one surface thereof and mounted on the first electrode structure and the second electrode structure of the package body. The Led package further includes a side inclined portion disposed to enclose side surfaces of the LED chip, including a light transmission material, and having an upwardly inclined surface. The LED package also includes a wavelength conversion layer disposed on a top surface of the LED chip and the inclined surface of the side inclined portion.

According to another aspect of the present disclosure, a method of manufacturing an LED package includes mounting an LED chip on a mounting surface of a package body. The method further includes applying a transparent resin to side surfaces of the LED chip to enclose the side surfaces and form a side inclined portion having an inclined surface extending from an edge of a top surface of the LED chip to the mounting surface of the package body. The method also includes forming a wavelength conversion layer to cover the top surface of the LED chip and the inclined surface of the side inclined portion.

The forming of the wavelength conversion layer may be performed by conformally coating a wavelength conversion material.

### BRIEF DESCRIPTION OF DRAWINGS

The above and other aspects, features and other advantages of the present disclosure will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the inventive concept. In the drawings, the thickness of layers and regions may be exaggerated for clarity.

FIG. 1A is a side cross-sectional view of a light emitting diode (LED) package according to an exemplary embodiment of the present disclosure and FIG. 1B is an enlarged view of an LED chip of FIG. 1A.

FIG. 2 is a side cross-sectional view of an LED package according to another exemplary embodiment of the present disclosure.

FIG. 3 is a side cross-sectional view of an LED package according to another exemplary embodiment of the present disclosure.

FIG. 4 is a side cross-sectional view of an LED package according to another exemplary embodiment of the present disclosure.

FIGS. 5 through 7 are views illustrating a method of manufacturing the LED package of FIG. 1.

FIGS. 8 through 11 are views illustrating a method of manufacturing the LED package of FIG. 4.

FIGS. 12 and 13 illustrate examples of an LED package according to an exemplary embodiment of the present disclosure applied to a backlight unit.

FIG. 14 illustrates an example of an LED package according to an exemplary embodiment of the present disclosure applied to a lighting device.

FIG. 15 illustrates an example of an LED package according to an exemplary embodiment of the present disclosure applied to a headlamp.

### DETAILED DESCRIPTION

Exemplary embodiments of the present disclosure are described in detail with reference to the accompanying drawings.

The disclosure may, however, be exemplified in many different forms and should not be construed as being limited to the specific exemplary embodiments set forth herein. Rather, these exemplary embodiments of the present disclosure are provided so that this disclosure will be thorough and complete, and will fully convey the scope of the disclosure to those skilled in the art.

In the drawings, the shapes and dimensions of elements maybe exaggerated for clarity, and the same reference numerals will be used throughout to designate the same or like elements.

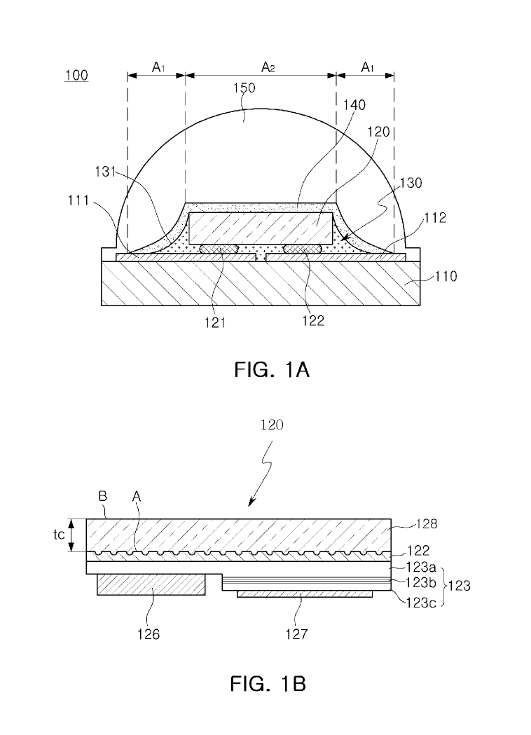

FIG. 1A is a side cross-sectional view of a light emitting diode (LED) package according to an exemplary embodiment of the present disclosure. FIG. 1B is an enlarged view of an LED chip of FIG. 1A.

With reference to FIG. 1A, an LED package 100 according to an exemplary embodiment of the present disclosure may include a package body 110, an LED chip 120 mounted on a surface of the package body 110, a side inclined portion 130 formed on side surfaces of the LED chip 120, and a wavelength conversion layer 140.

First and second electrode structures 111 and 112 may be formed on the package body 110. The LED chip 120 may be mounted on the first and second electrode structures 111 and 112. First and second electrodes 126 and 127 of the LED chip 120 (shown in FIG. 1B) may be electrically connected to the first and second electrode structures 111 and 112 using a conductive adhesive layer such as solder bumps 121 and 122 and the like.

Here, the package body 110 may be made of an organic resin material containing epoxy, triazine, silicon, polyimide, or the like, and other organic resin materials. In order to improve heat dissipation and light emission efficiency, the package body 110 may be made of a ceramic material having high heat resistance, superior thermal conductivity, and high reflectivity, such as Al₂O₃, AlN, or the like. The material of the package body 110 is not limited thereto, and various materials may be used for the package body 110 in consideration of heat dissipation, electrical connection, and the like of the LED package 100.

Apart from the above-described ceramic substrate, a printed circuit board, a lead frame, or the like may be used as the package body 110 according to the present embodiment.

With reference to FIG. 1B, the LED chip 120 may include a transparent substrate 128 having a first surface A and a second surface B opposite to the first surface A, a light emitting structure 123 disposed on the first surface A of the substrate 128, and the first and second electrodes 126 and 127 each connected to the light emitting structure 123.

The substrate 128 may be a semiconductor growth substrate made of sapphire, SiC, MgAl₂O₄, MgO, LiAlO₂, LiGaO₂, GaN or the like. Sapphire is a crystal having Hexa-Rhombo R3C symmetry and has a lattice constant of 13.001 Å (angstrom) along a C-axis and a lattice constant of 4.758 Å along an A-axis. Orientation planes of sapphire include a C (0001) plane, an A (11-20) plane, an R (1-102) plane, and the like. The C plane is mainly used as a substrate for nitride semiconductor growth because it facilitates the growth of a nitride film and is stable at high temperatures.

The substrate 128 may have the first and second surfaces A and B opposing each other, and at least one of the first and second surfaces A and B may be provided with uneven structures. The uneven structures may be formed by etching portions of the substrate 128. Alternatively, the uneven structures may be obtained by forming structures made of a heterogeneous material different from the material of the substrate 128.

As illustrated in FIG. 1B, in a case in which the uneven structures are formed on the first surface A of the substrate 128 provided as a growth surface for the light emitting structure 123, stress caused by a difference in crystal constants at an interface between the substrate 128 and a first conductivity type semiconductor layer 123a may be alleviated. For example, in a case in which a group III nitride semiconductor layer is grown on a sapphire substrate, dislocation may occur due to a difference in lattice constants of the substrate and the group III nitride semiconductor layer and may be transferred upwards, thereby degrading the crystalline quality of semiconductor layers.

According to the present embodiment, the uneven structures having convex portions are formed on the substrate 128, such that the first conductivity type semiconductor layer 123a may be grown on side surfaces of the concave portions, whereby the dislocation maybe prevented from being transferred upwards. Therefore, a high quality LED package may be provided, and internal quantum efficiency may be improved.

In addition, a path of light emitted from an active layer 123b may be diversified due to the uneven structures. Thus, a light absorption rate inside the semiconductor layers may decrease and a light scattering rate may increase, whereby light extraction efficiency may be improved.

Here, the substrate 128 may have a thickness t_{c} of 100 μm or less. For example, the thickness of the substrate 128 may be 1 μm to 20 μm, but is not limited thereto. Such a thickness range may be obtained by grinding the substrate provided for semiconductor growth. For example, the second surface B of the substrate, opposite to the first surface A thereof on which the light emitting structure 123 is formed, may be subjected to grinding, or may be subjected to lapping such that the second surface B is ground using a lap and lapping powder by abrasion and grinding actions.

The light emitting structure 123 may include the first conductivity type semiconductor layer 123a, the active layer 123b and a second conductivity type semiconductor layer 123c sequentially disposed on the first surface A of the substrate 128. The first and second conductivity type semiconductor layers 123a and 123c may be n-type and p-type semiconductor layers made of nitride semiconductors, respectively. The present inventive concept is not limited thereto. However, according to the present embodiment, the first and second conductivity type semiconductor layers 123a and 123c may be understood as referring to n-type and p-type semiconductor layers, respectively. The first and second conductivity type semiconductor layers 123a and 123c may be made of a material having a composition of AlₓIn_{y}Ga_{(1-x-y)}N, where 0≦x≦1, 0≦y≦1 and 0≦x+y≦1. For example, GaN, AlGaN, InGaN, or the like, may be used therefore.

The active layer 123b may be a layer for emitting visible light having a wavelength of approximately 350 nm to 680 nm. The active layer 123b may be formed of undoped nitride semiconductor layers having a single-quantum-well (SQW) structure or a multi-quantum-well (MQW) structure. For example, the active layer 123b may have an MQW structure in which quantum barrier layers and quantum well layers having a composition of AlₓIn_{y}Ga_{(1-x-y)}N (0≦x≦1, 0≦y≦1, and 0≦x+y≦1) are alternately stacked, such that the active layer 123b may have a predetermined energy bandgap and emit light through recombination of electrons and holes in quantum wells. In the case of the MQW structure, an InGaN/GaN structure may be used, for example. The first and second conductivity type semiconductor layers 123a and 123c and the active layer 123b may be formed using crystal growth processes known in the art such as metal organic chemical vapor deposition (MOCVD), molecular beam epitaxy (MBE), hydride vapor phase epitaxy (HVPE), or the like.

A buffer layer 122 may be disposed between the substrate 128 and the light emitting structure 123. In a case in which the light emitting structure 123 is grown on the substrate 128, for example, in a case in which a GaN thin film is grown as a light emitting structure on a heterogeneous substrate, lattice defects such as dislocation may occur due to a lattice constant mismatch between the substrate and the GaN thin film, and cracks may occur in the light emitting structure by the warpage of the substrate due to a difference between the coefficients of thermal expansion. In order to control these defects and warpage, the buffer layer 122 may be formed on the substrate 128 and then a light emitting structure formed in a desired structure, for example, a nitride semiconductor structure, may be formed thereon. The buffer layer 122 may be a low-temperature buffer layer formed at a temperature lower than a single crystal growth temperature, but is not limited thereto.

The buffer layer 122 may be made of a material having a composition of AlₓIn_{y}Ga_{1-x-y}N, where and 0≦y≦1, and particularly, GaN, AlN, and AlGaN may be used therefore. For example, the buffer layer may be an undoped GaN layer, which is not doped with impurities, formed in a uniform thickness.

The buffer layer is not limited thereto, and any structure improving crystalline properties of the light emitting structure 123 may be employed, and materials such as ZrB₂, HfB₂, ZrN, HfN, TiN, ZnO, or the like, may also be used. In addition, the buffer layer 122 may be formed by combining a plurality of layers or the composition thereof may be gradually varied.

The first and second electrodes 126 and 127 are provided to allow the first and second conductivity type semiconductor layers 123a and 123c to be electrically connected to a power source, and may be disposed to contact the first and second conductivity type semiconductor layers 123a and 123c, respectively.

The first and second electrodes 126 and 127 may be formed of a single layer or multilayer structure made of a conductive material having ohmic contact with the respective first and second conductivity type semiconductor layers 123a and 123c. For example, first and second electrodes 126 and 127 may be formed by depositing or sputtering at least one of gold (Au), silver (Ag), copper (Cu), zinc (Zn), aluminum (Al), indium (In), titanium (Ti), silicon (Si), germanium (Ge), tin (Sn), magnesium (Mg), tantalum (Ta), chromium (Cr), tungsten (W), ruthenium (Ru), rhodium (Rh), iridium (Ir), nickel (Ni), palladium (Pd), platinum (Pt), and a transparent conductive oxide (TCO). The first and second electrodes 126 and 127 may be disposed in the same direction, on the opposite of the substrate 128 based on the light emitting structure 123. The first and second electrodes 126 and 127 may be mounted on the first and second electrode structures 111 and 112 of the package body 110, as shown in FIG. 1A, which is a so called flip-chip type structure. In this case, the light emitted from the active layer 123b may pass through the substrate 128 and travel externally.

The side inclined portion 130 of FIG. 1A may enclose the side surfaces of the LED chip 120. The side inclined portion 130 may have an inclined surface 131 which is inclined toward the top thereof, and may be made of a light transmission material allowing a portion of the light generated in the active layer 123b to be emitted externally through the side surfaces of the LED chip 120.

A transparent resin may be used as the light transmission material, and for example, a material selected from the group consisting of a silicon resin, a modified silicon resin, an epoxy resin, a urethane resin, an oxetane resin, an acrylic resin, a polycarbonate resin, a polyimide resin, and a combination thereof may be used.

With regard to the shape applicable to the side inclined portion 130 of the present embodiment, the side inclined portion 130 may connect a top surface of the LED chip 120 to a mounting surface of the package body 110. The side inclined portion 130 may be formed to enclose all the side surfaces of the LED chip 120 so that the light emitted from the side surfaces of the LED chip 120 may all be transmitted therethrough. Hereinafter, the mounting surface of the package body 110 may refer to one surface of two opposing surfaces thereof on which the LED chip 120 is mounted.

The side inclined portion 130 may have at least one inclined surface 131, and the inclined surface 131 may be curved. The curved surface of the inclined surface 131 may be concave with respect to a straight line connecting an edge of the top surface of the LED chip 120 to the mounting surface of the package body 110. The straight line connecting the edge of the top surface of the LED chip 120 to the mounting surface of the package body 110 may form an angle of 10° to 80° with respect to the mounting surface of the package body 110. For example, the inclined angle may be approximately 45°.

The inclined surface 131 of the side inclined portion 130 may be formed by dispensing a liquid transparent resin to the LED chip 120. The amount of transparent resin may be adjusted to allow a surface of the transparent resin to be concavely curved due to surface tension.

The inclined surface 131 of the side inclined portion 130 may facilitate the wavelength conversion layer 140 to be formed conformally on the top and side surfaces of the LED chip 120 at a uniform thickness. Specifically, the wavelength conversion layer 140 formed on the LED chip 120 should have a uniform thickness in order to reduce color dispersion of light converted therein. However, it is difficult to form the thickness of the wavelength conversion layer 140 to be uniform at the edge of the top surface of the LED chip 120 and an edge of a surface of the LED chip 120 in contact with the mounting surface of the package body 110. For example, in a case in which the wavelength conversion layer 140 is formed by spray coating, it maybe formed relatively thick at the edge of the top surface of the LED chip 120 as compared to the other parts of the LED chip 120, while it may be formed relatively thin at the edge of the surface of the LED chip 120 in contact with the mounting surface of the package body 110 as compared to the other parts of the LED chip 120.

Since the side inclined portion 130 according to the present embodiment has the inclined surface 131 connecting the edge of the top surface of the LED chip 120 to the mounting surface of the package body 110 along the side surfaces of the LED chip 120, the thickness of the wavelength conversion layer 140 formed on the inclined surface 131 may be substantially uniform through an effect of conformal coating. Therefore, the LED package 100 according to the present embodiment may include the wavelength conversion layer 140 formed above the side surfaces of the LED chip 120 by a conformal coating, whereby a color temperature difference may be reduced and color quality may be improved.

In addition, the concave inclined surface 131 of the side inclined portion 130 may change a path of light emitted from the side surfaces of the LED chip 120 toward the top surface of the LED chip 120, thereby allowing a greater amount of light to be emitted toward the top surface of the LED chip 120.

The wavelength conversion layer 140 may include a wavelength conversion material excited by light emitted from the light emitting structure 123 to convert at least a portion of the light into light having a different wavelength, and the wavelength conversion material may be phosphors or quantum dots. As described above, the wavelength conversion layer 140 may include a region A₂ formed on the top surface of the LED chip 120 and a region A₁ formed on the inclined surface 131 of the side inclined portion 130, and may be formed at a substantially uniform thickness by a conformal coating.

According to the present embodiment, the inclined surface 131 is provided around the side surfaces of the LED chip 120, thereby allowing all the top and side surfaces of the LED chip 120 to be covered with the wavelength conversion layer 140 having a substantially uniform thickness. Thus, a color temperature difference occurring when the thickness of the wavelength conversion layer 140 is not uniform may be effectively improved, and the LED package 100 may obtain a superior color quality.

In addition, light emission efficiency of the LED package 100 may be further improved. Specifically, the wavelength conversion material contained in the wavelength conversion layer 140, for example, phosphors, may absorb at least a portion of light emitted from the LED chip 120 (self absorption) to cause a loss of light. According to the present embodiment, the amount of phosphors required for uniform color characteristics may be reduced by minimizing the thickness of the wavelength conversion layer 140, and thus, the amount of light self-absorbed by the phosphors may be reduced.

A lens unit 150 may be disposed above the wavelength conversion layer 140 such that it may seal the wavelength conversion layer 140. The lens unit 150 may have various shapes to control the distribution of light emitted from the LED chip 120. For example, the lens unit 150 may be provided as a convex lens, a concave lens, an elliptical lens, or the like, thereby controlling the light distribution.

A material for the lens unit 150 is not particularly limited, as long as it can provide light transmission. An insulating resin having light transmission such as a silicon resin composition, a modified silicon resin composition, an epoxy resin composition, a modified epoxy resin composition, an acrylic resin composition, or the like, may be used therefore. In addition, a hybrid resin including at least one of a silicon resin, an epoxy resin, and a fluoride resin may be used. The material for the lens unit 150 is not limited to organic materials, and may be inorganic materials having superior light stability such as glass, silica gel, or the like.

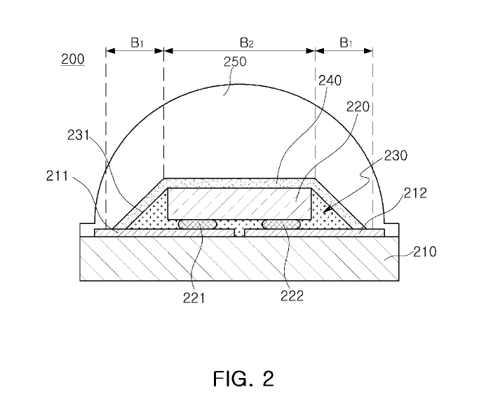

Hereinafter, an LED package according to another exemplary embodiment of the present disclosure will be described. FIG. 2 is a side cross-sectional view of an LED package according to another exemplary embodiment of the present disclosure.

Unlike the exemplary embodiment described above with reference to FIG. 1, an inclined surface 231 of a side inclined portion 230 according to the present embodiment is flat. Since other features of this embodiment are the same as those of the above-described embodiment, features that are different will mainly be described.

As shown in FIG. 2, an LED package 200 according to another exemplary embodiment of the present disclosure, like the LED package according to the above-described embodiment, may include a package body 210, an LED chip 220 mounted on a surface of the package body 210, the side inclined portion 230 formed on side surfaces of the LED chip 220, and a wavelength conversion layer 240.

The inclined surface 231 of the side inclined portion 230 may form a predetermined angle of inclination with respect to a mounting surface of the package body 210.

The wavelength conversion layer 240 may include a region B₂ formed on a top surface of the LED chip 220 and a region B₁ formed on the inclined surface 231 of the side inclined portion 230. Unlike the above-described embodiment, the region B₁ formed on the inclined surface 231 of the side inclined portion 230 may form a predetermined angle of inclination. Therefore, according to the present embodiment, the wavelength conversion layer 240 formed on the inclined surface 231 of the side inclined portion 230 has such an inclined portion at a predetermined angle, thus changing a path of light emitted from the side surfaces of the LED chip 220 downwardly, whereby a light emission range of the LED package 200 may be expanded.

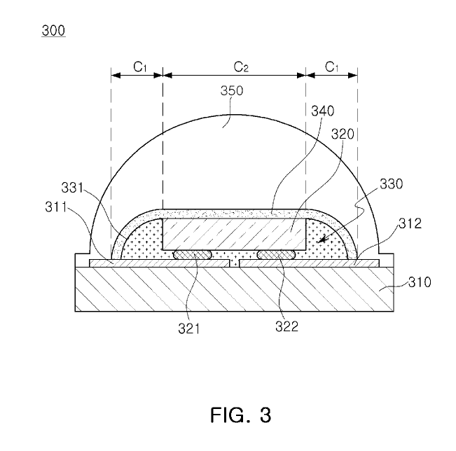

Hereinafter, an LED package according to another exemplary embodiment of the present disclosure will be described. FIG. 3 is a side cross-sectional view of an LED package according to another exemplary embodiment of the present disclosure.

Unlike the exemplary embodiment described above with reference to FIG. 1, an inclined surface 331 of a side inclined portion 330 according to the present embodiment is convexly curved with respect to a straight line connecting an edge of a top surface of an LED chip 320 to a mounting surface of a package body 310. Since other features of this embodiment are the same as those of the above-described embodiment, features that are different will mainly be described.

As shown in FIG. 3, an LED package 300 according to another exemplary embodiment of the present disclosure, like the LED package according to the above-described embodiment, may include the package body 310, the LED chip 320 mounted on a surface of the package body 310, the side inclined portion 330 formed on side surfaces of the LED chip 320, and a wavelength conversion layer 340. A lens unit 350 may be disposed above the wavelength conversion layer 340 such that it may seal the wavelength conversion layer 340.

The inclined surface 331 of the side inclined portion 330 may be convexly curved with respect to the straight line connecting the edge of the top surface of the LED chip 320 to the mounting surface of the package body 310.

The wavelength conversion layer 340 may include a region C₂ formed on the top surface of the LED chip 320 and a region C₁ formed on the inclined surface 331 of the side inclined portion 330. Unlike the above-described embodiment, the region C₁ formed on the inclined surface 331 of the side inclined portion 330 has a convex shape, thus changing a path of light emitted from the side surfaces of the LED chip 320 downwardly, whereby a light emission range of the LED package 300 may be further expanded.

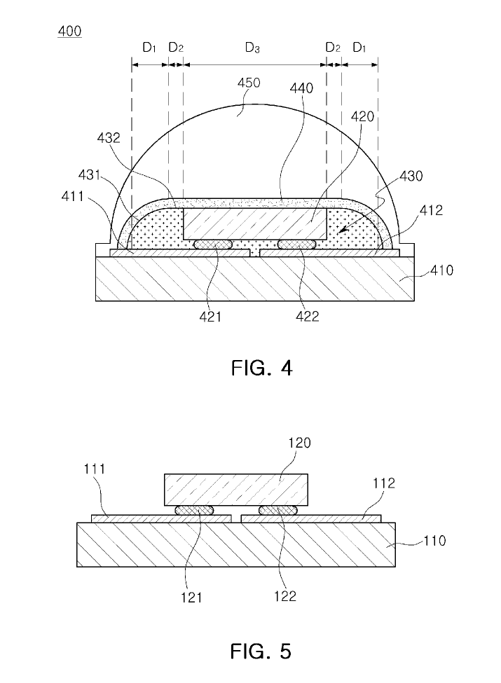

Hereinafter, an LED package according to a modified exemplary embodiment of the present disclosure will be described. FIG. 4 is a side cross-sectional view of an LED package according to a modified exemplary embodiment of the present disclosure.

Unlike the exemplary embodiment described above with reference to FIG. 3, a side inclined portion 430 according to the present embodiment is extended to have a flat surface 432 on the same level as a top surface of an LED chip 420. Since other features of this embodiment are the same as those of the above-described embodiment, features that are different will mainly be described.

As shown in FIG. 4, an LED package 400 according to a modified exemplary embodiment of the present disclosure, like the LED package according to the above-described embodiment, may include a package body 410, the LED chip 420 mounted on a surface of the package body 410, the side inclined portion 430 formed on side surfaces of the LED chip 420, and a wavelength conversion layer 440. A lens unit 450 may be disposed above the wavelength conversion layer 440 such that it may seal the wavelength conversion layer 440.

The side inclined portion 430 may have the inclined surface 431 convexly curved with respect to a straight line connecting an edge of the top surface of the LED chip 420 to a mounting surface of the package body 410, and the flat surface 432 extended from the edge of the top surface of the LED chip 420 on the same level.

The wavelength conversion layer 440 may include a region D₃ formed on the top surface of the LED chip 420, a region D₂ formed on the flat surface 432 of the side inclined portion 430 on the same level as the top surface of the LED chip 420, and a region D₁ formed on the inclined surface 431 of the side inclined portion 430. Unlike the above-described embodiment, the flat surface 432 is extended from the side surfaces of the LED chip 420, thereby forming a large light emitting surface.

Hereinafter, a method of manufacturing the LED package 100 depicted in FIG. 1A will be described with reference to FIGS. 5 through 7.

As illustrated in FIG. 5, the LED chip 120 may be mounted on the first and second electrode structures 121 and 122 formed on one surface of the package body 110. In a case in which the LED chip 120 is mounted in a flip-chip manner, the solder bumps 121 and 122 may be used. However, the mounting method is not limited thereto, and various mounting methods may be used.

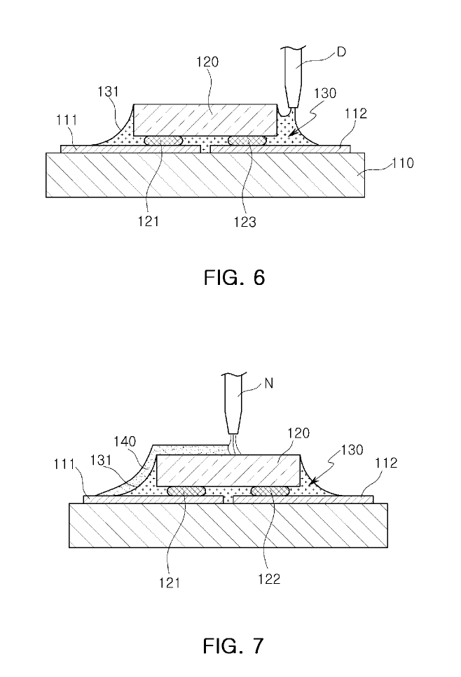

Next, as illustrated in FIG. 6, a transparent resin may be applied to the side surfaces of the LED chip 120 using a dispenser D, thereby forming the side inclined portion 130. Here, the amount of the transparent resin applied may be limited to an amount allowing a surface of the transparent resin to form a concave shape due to surface tension. When a top portion of the side inclined portion 130 is formed to contact the edge of the top surface of the LED chip 120, that is, the side inclined portion 130 and the top surface of the LED chip 120 are naturally connected, the wavelength conversion layer 140 to be applied in the next operation may be prevented from being relatively thick at the edge portion of the top surface of the LED chip 120, whereby the wavelength conversion layer 140 may be obtained by a conformal coating.

Then, as illustrated in FIG. 7, a wavelength conversion material may be applied to the inclined surface 131 of the side inclined portion 130 and the top surface of the LED chip 120, thereby forming the wavelength conversion layer 140. Here, the wavelength conversion material may be applied thereto through a spraying method using a nozzle N, but the application of the wavelength conversion material is not limited thereto. Various methods for forming the wavelength conversion layer 140 to have a substantially uniform thickness in a conformal coating manner may be used. Through the above-described processes, the LED package 100 of FIG. 1A may be manufactured.

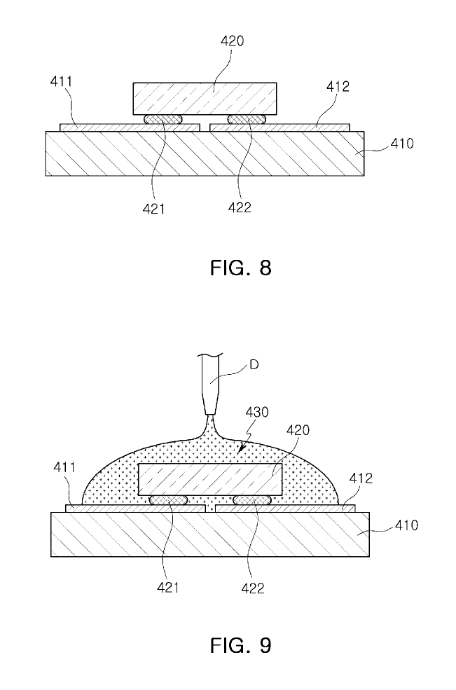

Hereinafter, a method of manufacturing the LED package 400 depicted in FIG. 4 will be described with reference to FIGS. 8 through 11.

As illustrated in FIG. 8, the LED chip 420 may be mounted on first and second electrode structures 421 and 422 formed on one surface of the package body 410. In a case in which the LED chip 420 is mounted in a flip-chip manner, solder bumps 421 and 422 may be used. However, the mounting method is not limited thereto, and various mounting methods may be used.

Next, as illustrated in FIG. 9, a transparent resin may be applied using a dispenser D to enclose the LED chip 420, thereby forming the side inclined portion 430. Here, the amount of the transparent resin applied may be adjusted to cover all of the side surfaces of the LED chip 420, but it is not necessary to cover the entirety of the top surface of the LED chip 420 with the transparent resin.

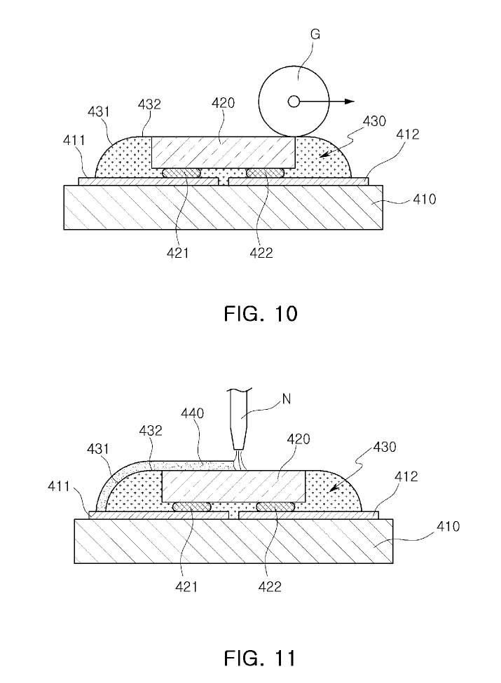

Then, as illustrated in FIG. 10, after the transparent resin is cured, a portion of the transparent resin may be removed to expose the top surface of the LED chip 420. The transparent resin applied to the top surface of the LED chip 420 may be removed using a grinder, but the removal method is not limited thereto. Various methods, such as a chemical etching method, a physical etching method, and the like, may be used.

Here, the transparent resin may be removed by grinding, where the flat surface 432 on the same level as the top surface of the LED chip 420 may be formed in the region of the side inclined portion 430 from which the transparent resin is removed.

Then, as illustrated in FIG. 11, a wavelength conversion material may be applied to the inclined surface 431 and the flat surface 432 of the side inclined portion 430 and the top surface of the LED chip 420, thereby forming the wavelength conversion layer 440. Here, the wavelength conversion material may be applied thereto through a spraying method, but the application of the wavelength conversion material is not limited thereto. Various methods for forming the wavelength conversion layer 440 to have a substantially uniform thickness in a conformal coating manner may be used. Through the above-described processes, the LED package 400 of FIG. 4 may be manufactured.

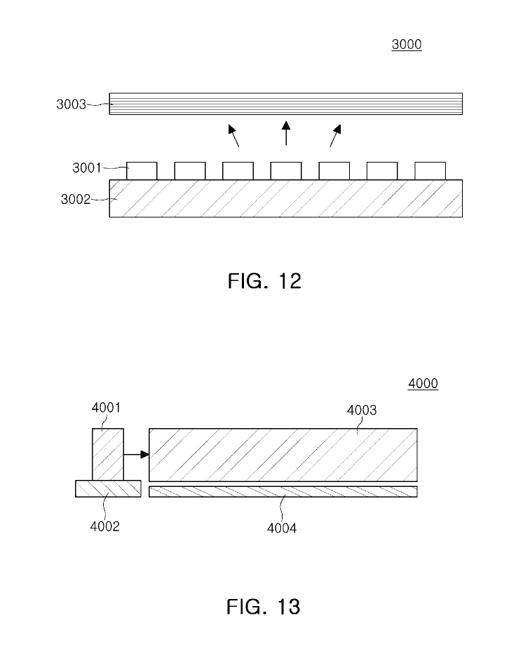

FIGS. 12 and 13 illustrate examples of an LED package according to an exemplary embodiment of the present disclosure applied to a backlight unit.

With reference to FIG. 12, a backlight unit 3000 may include at least one light source 3001 mounted on a substrate 3002 and at least one optical sheet 3003 disposed thereabove. The light source 3001 may be an LED package having the same structure as the above-described structures of FIGS. 1A and 4 or a structure similar thereto, or a chip-on-board (COB) type package in which any one of the LED packages of FIGS. 1 through 4 is directly mounted on the substrate 3002.

The light source 3001 in the backlight unit 3000 of FIG. 12 emits light toward a liquid crystal display (LCD) device disposed thereabove, whereas a light source 4001 mounted on a substrate 4002 in a backlight unit 4000 according to another embodiment illustrated in FIG. 13 emits light laterally, and the light is incident to a light guide plate 4003 such that the backlight unit 4000 may serve as a surface light source. The light travelling to the light guide plate 4003 may be emitted upwardly and a reflective layer 4004 maybe formed below a lower surface of the light guide plate 4003 in order to improve light extraction efficiency.

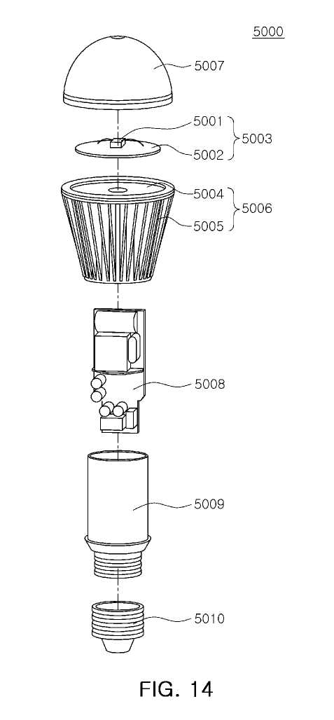

FIG. 14 illustrates an example of an LED package according to an exemplary embodiment of the present disclosure applied to a lighting device.

With reference to an exploded perspective view of FIG. 14, a lighting device 5000 is exemplified as a bulb-type lamp, and may include a light emitting module 5003, a driver 5008 and an external connector 5010. In addition, the lighting device 5000 may further include exterior structures such as external and internal housings 5006 and 5009, a cover 5007, and the like. The light emitting module 5003 may include a light source 5001 having the same structure as that of the LED package 100, 200, 300 or 400 of FIGS. 1A through 4 or a structure similar thereto, and a circuit board 5002 having the light source 5001 mounted thereon. In the present embodiment, a single light source 5001 is mounted on the circuit board 5002 by way of example. However, a plurality of light sources may be mounted thereon as necessary.

The external housing 5006 may serve as a heat radiator and may include a heat sink plate 5004 directly contacting the light emitting module 5003 to thereby improve heat dissipation, and heat radiating fins 5005 surrounding a lateral surface of the lighting device 5000. The cover 5007 may be disposed above the light emitting module 5003 and have a convex lens shape. The driver 5008 may be disposed inside the internal housing 5009 and be connected to the external connector 5010 such as a socket structure to receive power from an external power source. In addition, the driver 5008 may convert the received power into power appropriate for driving the light source 5001 of the light emitting module 5003 and supply the converted power thereto. For example, the driver 5008 may be provided as an AC-DC converter, a rectifying circuit part, or the like.

Although not shown, the lighting device 5000 may further include a communications module.

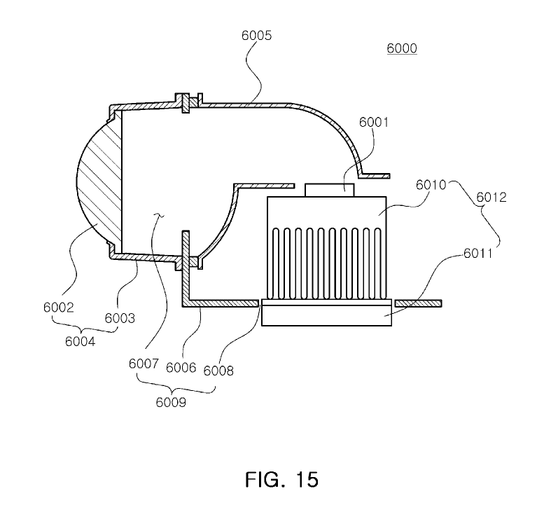

FIG. 15 illustrates an example of an LED package according to an exemplary embodiment of the present disclosure applied to a headlamp.

With reference to FIG. 15, a headlamp 6000 used in a vehicle or the like may include a light source 6001, a reflector 6005 and a lens cover 6004, and the lens cover 6004 may include a hollow guide part 6003 and a lens 6002. The light source 6001 may include at least one LED package illustrated in FIGS. 1A through 4.

The headlamp 6000 may further include a heat radiator 6012 externally dissipating heat generated in the light source 6001. The heat radiator 6012 may include a heat sink 6010 and a cooling fan 6011 in order to effectively dissipate heat. In addition, the headlamp 6000 may further include a housing 6009 allowing the heat radiator 6012 and the reflector 6005 to be fixed thereto and supporting them. The housing 6009 may include a body 6006 and a central hole 6008 formed in one surface thereof, to which the heat radiator 6012 is coupled.

The housing 6009 may include a forwardly open hole 6007 formed in the other surface thereof integrally connected to one surface thereof and bent in a direction perpendicular thereto. The reflector 6005 may be fixed to the housing 6009, such that light generated in the light source 6001 may be reflected by the reflector 6005, pass through the forwardly open hole 6007, and be emitted outwards.

As set forth above, an LED package according to exemplary embodiments of the present disclosure may have a reduced color temperature difference and improved color quality.

While exemplary embodiments have been shown and described above, it will be apparent to those skilled in the art that modifications and variations could be made without departing from the spirit and scope of the present disclosure as defined by the appended claims.

What is claimed is:

1. A light emitting diode (LED) package comprising:
a package body;
an LED chip mounted on the package body;
a side inclined portion disposed to enclose side surfaces of the LED chip, including a light transmission material, and having an upwardly inclined surface; and
a wavelength conversion layer disposed on a top surface of the LED chip and the inclined surface of the side inclined portion.

2. The LED package of claim 1, wherein the inclined surface extends from an edge of the top surface of the LED chip to a mounting surface of the package body.

3. The LED package of claim 1, wherein the inclined surface is curved.

4. The LED package of claim 3, wherein the inclined surface is concavely curved with respect to a straight line connecting an edge of the top surface of the LED chip to a mounting surface of the package body.

5. The LED package of claim 3, wherein the inclined surface is convexly curved with respect to a straight line connecting an edge of the top surface of the LED chip to a mounting surface of the package body.

6. The LED package of claim 1, wherein the side inclined portion extends to have a flat surface on the same level as the top surface of the LED chip.

7. The LED package of claim 1, wherein the light transmission material is a transparent resin.

8. The LED package of claim 7, wherein the transparent resin is selected from the group consisting of a silicon resin, a modified silicon resin, an epoxy resin, a urethane resin, an oxetane resin, an acrylic resin, a polycarbonate resin, a polyimide resin, and a combination thereof.

9. The LED package of claim 1, wherein the wavelength conversion layer has a substantially uniform thickness.

10. The LED package of claim 1, further comprising a lens unit sealing the wavelength conversion layer.

11. An LED package comprising:
a package body including a first electrode structure and a second electrode structure;
an LED chip having a first electrode and a second electrode disposed on one surface thereof and mounted on the first electrode structure and the second electrode structure of the package body;
a side inclined portion disposed to enclose side surfaces of the LED chip, including a light transmission material, and having an upwardly inclined surface; and
a wavelength conversion layer disposed on a top surface of the LED chip and the inclined surface of the side inclined portion.

12. The LED package of claim 11, wherein the inclined surface extends from an edge of the top surface of the LED chip to a mounting surface of the package body.

13. The LED package of claim 11, wherein the inclined surface is concavely curved with respect to a straight line connecting an edge of the top surface of the LED chip to a mounting surface of the package body.

14. The LED package of claim 11, wherein the inclined surface is convexly curved with respect to a straight line connecting an edge of the top surface of the LED chip to a mounting surface of the package body.

15. A method of manufacturing an LED package, the method comprising:
mounting an LED chip on a mounting surface of a package body;
applying a transparent resin to side surfaces of the LED chip to enclose the side surfaces and form a side inclined portion having an inclined surface extending from an edge of a top surface of the LED chip to the mounting surface of the package body; and
forming a wavelength conversion layer to cover the top surface of the LED chip and the inclined surface of the side inclined portion.

16. The method of claim 15, wherein the forming of the wavelength conversion layer is performed by conformally coating a wavelength conversion material.

17. The method of claim 15, further comprising:
curing the applied transparent resin; and
removing a portion of the cured transparent resin to expose the top surface of the LED chip.

18. The method of claim 15, further comprising forming a lens unit to seal the wavelength conversion layer.

19. The method of claim 15, wherein the package body includes a first electrode structure and a second electrode structure, and
wherein the LED chip includes a first electrode and a second electrode disposed on one surface thereof, and
wherein the mounting of the LED chip on the mounting surface of the package body is performed by respectively mounting the first electrode and the second electrode on the first electrode structure and the second electrode structure.

20. The method of claim 15, wherein the inclined surface is curved.
